(19) United States
(12) Patent Application Publication
(10) Pub. No.: US 2015/0270015 A1
(43) Pub. Date: Sep. 24, 2015

(54) MEMORY MAPPING

(71) Applicant: Micron Technology, Inc., Boise, ID (US)

(72) Inventors: Richard C. Murphy, Boise, ID (US); Troy A. Manning, Meridian, ID (US)

(73) Assignee: Micron Technology, Inc., Boise, ID (US)

(21) Appl. No.: 14/219,639

(22) Filed: Mar. 19, 2014

(51) Int. Cl. G11C 29/18; G11C 29/44

(52) U.S. Cl. CPC G11C 29/18; G11C 29/44; G11C 2029/1806; G11C 2029/4402

(57) ABSTRACT

The present disclosure includes apparatuses, electronic device readable media, and methods for memory mapping. One example method can include testing a memory identifier against an indication corresponding to a set of mapped memory identifiers, and determining a memory location corresponding to the memory identifier responsive to testing.

### TECHNICAL FIELD

The present disclosure relates generally to semiconductor memory and methods, and more particularly, to apparatuses, electronic device readable media, and methods for memory mapping.

### BACKGROUND

Memory devices are typically provided as internal, semiconductor, integrated circuits in computing devices or other electronic devices. There are many different types of memory including volatile and non-volatile memory. Volatile memory can require power to maintain its data (e.g., user data, error data, etc.) and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory can experience failures of individual or groups of memory cells, either initially, e.g., after manufacture, or during/after use. Memory redundancy mechanisms can be used to overcome particular failures of memory cells. Redundancy mechanisms for certain memory types, e.g., DRAM, are largely static and consist of hardware remapping of memory identifiers, e.g., logical addresses such as processor-side memory addresses, to rows and/or columns in the memory, such as by reprogramming fuses to “hard wire” a corrected memory structure based on failure of memory cell(s) detected during testing. Such hardware redundancy mechanisms can effectively correct initial failures of individual or groups of memory cells but are not effective to correct memory failures occurring during/after the memory is placed into service, e.g., during/after use.

### BRIEF DESCRIPTION OF THE DRAWINGS

FIG. 1 illustrates a block diagram of an apparatus in the form of a computing device including a number of processors, a number of memory devices, and an interface therebetween in accordance with a number of embodiments of the present disclosure.

FIG. 2 illustrates a mapping filter operation tuned for elements included in a set between a processor and a memory in accordance with a number of embodiments of the present disclosure.

FIG. 3 illustrates mapping utilizing a filter and associative data structure in accordance with a number of embodiments of the present disclosure.

FIG. 4 is a block diagram of an apparatus in the form of a computing system including a memory system in accordance with a number of embodiments of the present disclosure.

FIG. 5 illustrates a block diagram of an apparatus in the form of a computing device including a memory device and a number of requesting devices in accordance with a number of embodiments of the present disclosure.

### DETAILED DESCRIPTION

The present disclosure includes apparatuses, electronic device readable media, and methods for memory mapping. One example method can include testing a memory identifier against an indication corresponding to a set of mapped memory identifiers, and determining a memory location, e.g., physical memory location, corresponding to the memory identifier responsive to testing.

The memory mapping techniques described in the present disclosure can be used to dynamically select between alternative memory mappings. For example, dynamic memory mapping can be used to remap memory identifiers, e.g., processor-side addresses, to new memory locations such as upon failure of a portion of a memory, e.g., block(s). The memory identifiers for the failed memory portion can be remapped to new memory locations that are not failed. As used herein, remapping can refer to a subsequent mapping, e.g., according to a second mapping that is implemented after the memory identifier has been previously mapped according to a first mapping. For example, a memory address may be initially mapped to a first memory location and subsequently remapped to a second memory location.

Where alternative memory mapping is possible, a test can be used to determine to which alternative memory mapping the memory identifier is presently subject. For example, a test can be used to determine if a particular memory identifier has been remapped from another memory mapping (e.g., a default, initial, original, previous or primary memory mapping). The remapping test can be accomplished using an associative data structure, e.g., content addressable memory in which failed portions of memory are remapped. The portions of memory that are remapped can be blocks, for example, or other groups of memory cells. An associative date structure can be a data table indexed by a memory identifier, for example. However, associative data structure look-ups are expensive in terms of area and energy.

According to various embodiments of the present disclosure, the associative data structure can be replaced or supplemented with, for example, a two part process. First, a memory identifier can be tested to determine, e.g., ascertain, whether the memory identifier is subject to an alternative mapping, e.g., remapped, using one or more filters, e.g., skip list(s), Bloom filter(s). A skip list can be a listing of memory identifiers for which some action is, or is not, taken, e.g., memory identifiers that are not re-mapped can be skipped from searching in a data structure of remapped memory identifiers. When the memory identifier is determined to not be subject to the alternative mapping, the original mapping can be used to determine the corresponding memory location. Or when the memory identifier is determined to be subject to the alternative mapping, the alternative mapping can be used to determine the corresponding memory location. The alternative mapping can be an associative data structure, but it is only searched after it has been determined that the memory identifier is (or at least may be) subject to the alternative mapping, thereby realizing a power saving by not having to search the associative data structure of the alternative mapping for every memory identifier. The alternative mapping can also be implemented using deterministic techniques, but again, only after it is established that the memory identifier is not subject to another, e.g., original, memory mapping. Testing may be implemented by a plurality of filters, such as an arrangement that performs a union or intersection of Bloom filters or that utilizes counting filter(s) to provide a way to implement a delete operation on a Bloom filter without recreating the Bloom filter anew. Various embodiments of the present disclosure can be implemented using other arrangements of a plurality of filters.

The methods of the present disclosure can be used to implement dynamic memory mapping. Dynamic memory mapping can be utilized with various types of memory. For example, portions, e.g., block(s) of NAND flash memory can wear with usage and eventually be determined by a controller as no longer fit for reliable use. Dynamic memory mapping can be used to periodically remap processor-side memory identifiers, e.g., addresses, from bad block(s) of memory locations to other memory locations that are not failed. Even if not failed, dynamic remapping according to the present disclosure can be used to remap between memory identifiers and memory locations based on wear or other criteria.

The dynamic memory mapping capabilities described herein can be implemented alone, or in conjunction with static remapping techniques. The memory mapping techniques of the present disclosure can be particularly useful where memory identifier remapping is relatively infrequent or where slower look-up times can be tolerated for failed blocks as an alternative to including or using structure and power capabilities to maintain and operate an associative data structure that includes remapped memory identifiers. Using a filter to first determine whether a particular memory identifier has been remapped can, for example, have significant power, area, and performance advantages over maintaining an associative data structure to reflect memory identifiers that are remapped and/or those that are not remapped.

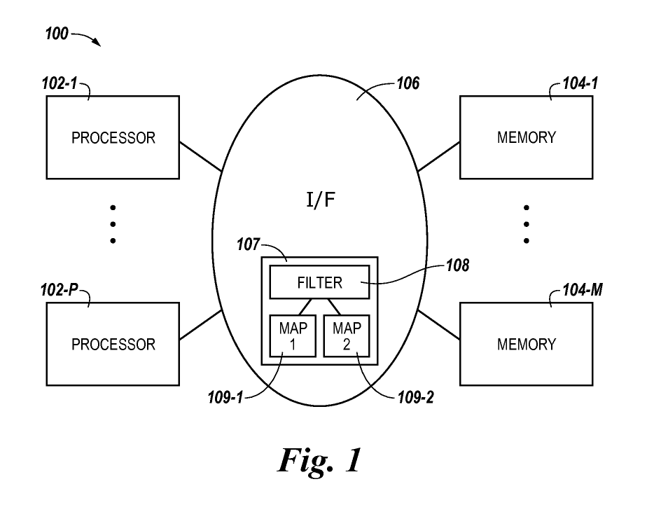

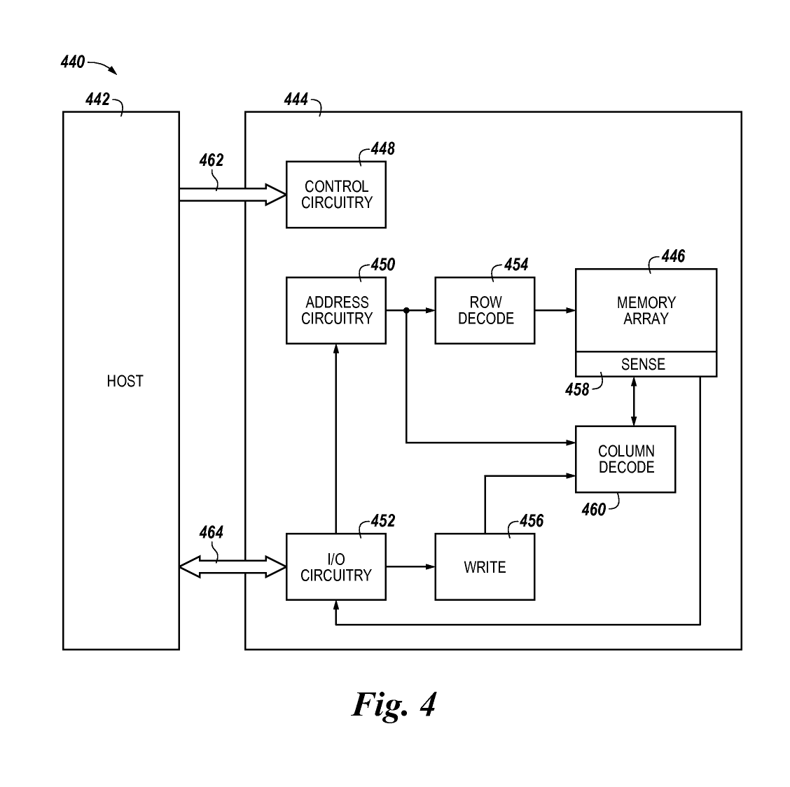

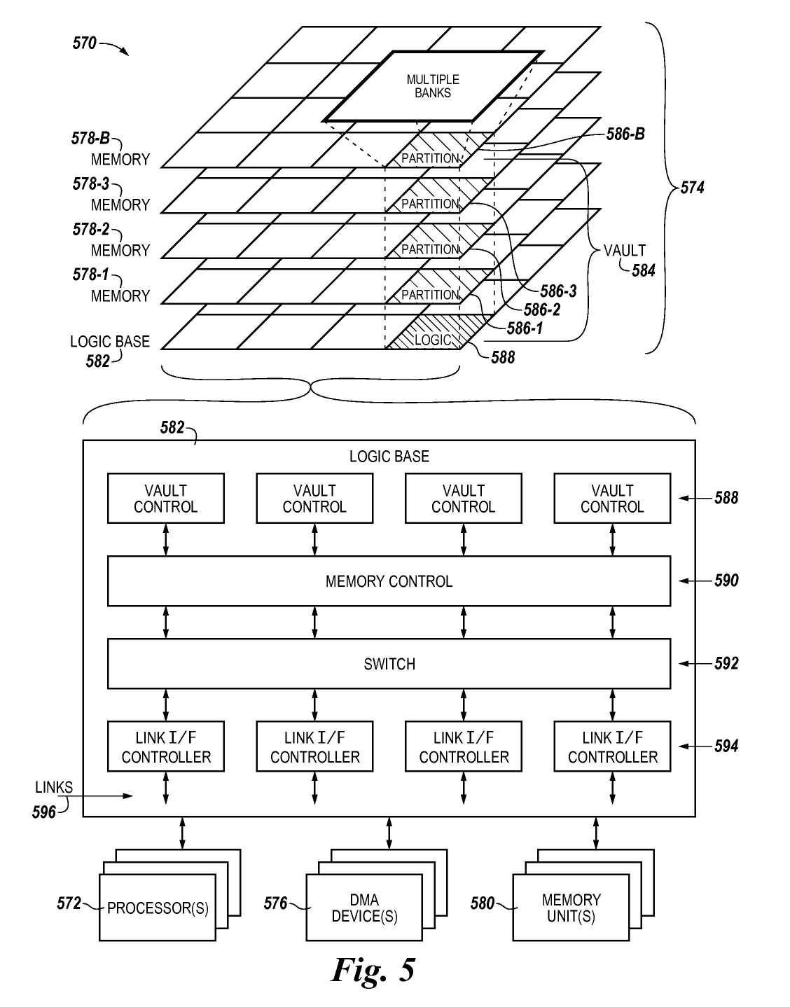

Dynamic memory mapping, e.g., redundancy management and remapping, can be implemented in computing systems comprising non-deterministic memory timings or any part of an abstracted memory interface, such as the computing device illustrated in FIG. 1 including a number of processing resources (sometimes referred to hereinafter as “processors,” a number of memory devices, and an interface therebetween. Dynamic memory mapping can also be implemented in a computing system including a memory system communicatively coupled to a discrete host as described with respect to FIG. 4, and/or in a processing in memory (PIM) configuration, solid state drive (SSD), a logic chip/SoC in a 2.5D packaging configuration, or a Hybrid Memory Cube (HMC) based on logic in a chip within the HMC as described with respect to FIG. 5, among others.

While this disclosure includes discussion of various memory mapping techniques and apparatuses in terms of remapping, e.g., from a previous mapping, the memory mapping techniques disclosed herein can be implemented in other circumstances, including directing memory mapping to an appropriate alternative mapping based on operating criteria. That is, a memory identifier may not have been previously mapped to a first memory location and subsequently remapped to a second memory location.

Rather, a computing system can be fabricated and/or implemented such that a memory identifier can be subject to a first memory mapping under certain conditions and subject to a second memory mapping under different conditions, with a memory mapping filter being used to control selection of the appropriate memory mapping. Furthermore, remapping suggests that a particular memory identifier is mapped according to more than one mapping, e.g., an original mapping and a subsequent remapping. However, embodiments of the present disclosure can be used to select a mapping in which a memory identifier is included and not to select a mapping in which the memory identifier is not included. Such a selection is not a remapping but rather a selection of mapping.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, the designators “B”, “L”, “M”, “N”, and “P”, particularly with respect to reference numerals in the drawings, indicates that a number of the particular feature so designated can be included. As used herein, “a number of” a particular thing can refer to one or more of such things, e.g., a number of memory devices can refer to one or more memory devices.

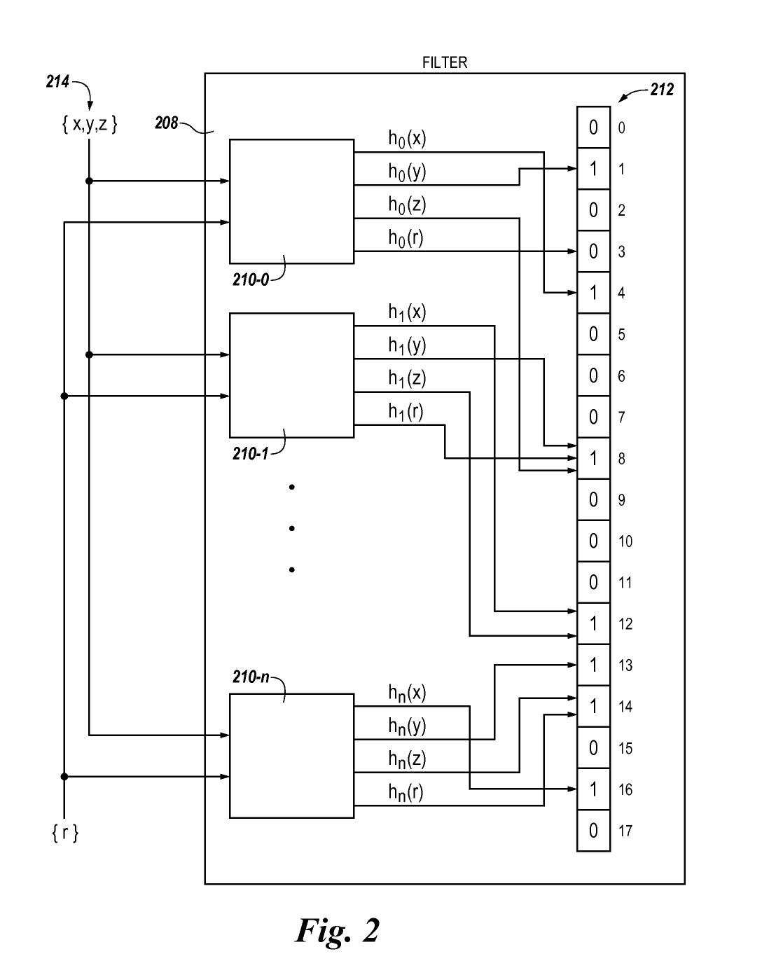

The figures herein follow a numbering convention in which the first digit or digits correspond to the drawing figure number and the remaining digits identify an element or component in the drawing. Similar elements or components between different figures may be identified by the use of similar digits. For example, 108 may reference element “08” in FIG. 1, and a similar element may be referenced as 208 in FIG. 2. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention, and should not be taken in a limiting sense.

FIG. 1 illustrates a block diagram of an apparatus in the form of a computing device 100 including a number of processors 102-1, . . . , 102-P, a number of memory devices 104-1, . . . , 104-M, and an interface 106 therebetween in accordance with a number of embodiments of the present disclosure. As used herein, a computing device 100, a processor 102, a memory device 104, or an interface 106 might also be separately considered an “apparatus.” The computing device 100 can be any electronic device including a processor and memory storing data that is accessed by the processor. Examples of computing devices 100 include supercomputers, personal computers, video cards, sound cards, and mobile electronic devices such as laptop computers, tablets, smartphones, and the like.

The processors 102-1, . . . , 102-P can be any type of general purpose processors. The memory devices 104-1, . . . , 104-M can store data that is operated on by the processors 102-1, . . . , 102-P. Examples of memory devices include DRAM and HMC, among others. However, according to a number of embodiments of the present disclosure, the memory devices 104-1, . . . , 104-M can control their timing independently of the processors 102-1, . . . , 102-P.

Interface 106 can include a memory mapping module 107. Memory mapping module 107 can be implemented as non-transitory electronic device readable medium storing a set of instructions executable by an electronic device, and may be implemented in part by an apparatus, e.g., hardware such as circuits that can include fuses and/or other programmable circuit elements. Memory mapping module 107 can include a mapping filter 108 and a plurality of mapping mechanisms, illustrated in FIG. 1 by a first mapping mechanism 109-1 and a second mapping mechanism 109-2. Mapping mechanisms are not limited to mechanical implementations such as circuits with programmable circuit elements, e.g., fuses. Although only one filter and two mapping mechanisms are shown in FIG. 1, embodiments of the present disclosure are not so limited and may include more filters and/or mapping mechanisms arranged in various configurations. Also, while FIG. 1 shows interface 106 comprising memory mapping module 107, embodiments of the present disclosure are not so limited and one or more memory mapping modules 107 may be alternatively located outside of interface 106. For instance, memory mapping modules 107 may be associated with each of the individual memory devices 104-1, . . . , 104-M.

FIG. 2 illustrates a mapping filter operation tuned for elements included in a set between a processor and a memory in accordance with a number of embodiments of the present disclosure. FIG. 2 shows a mapping filter 208 that can be analogous to the mapping filter 108 shown in FIG. 1. Mapping filter 208 can be used to select between a plurality of mappings, such as those that map processor-side addresses to memory locations. One example of selecting between a plurality of mappings is for mapping filter 208 to be used to determine if a memory identifier has been remapped from a previous mapping. For example, the memory identifier may have been initially mapped according to a first, e.g., initial or default, mapping, but due, for example, to failure of a first memory location corresponding to the memory identifier according to the first mapping, the memory identifier may be remapped to a second memory location, e.g., that is not failed. In this manner, mapping filter 208 can be used to select between the mapping mechanism implementing remapping or the mapping mechanism implementing the initial, default, or previous mapping mechanism.

According to various embodiments, mapping filter 208 can be a filter that indicates inclusion, or exclusion, of elements from a particular set of elements. For example, the set of elements may be memory identifiers that have been remapped. Each remapped memory identifier can be included in the set of remapped identifiers by tuning the filter to indicate inclusion as remapping is accomplished. Thereafter, the filter can be used in selecting a first, e.g., initial or default, mapping for those memory identifiers that have not been remapped, and a second, e.g., remapped, mapping for those memory identifiers that have been remapped.

With respect to remapping determinations, false negative results, e.g., particular element indicated not to be in the set of remapped memory identifiers, may be more problematic than false positive results, e.g., particular element indicated to be in the set of remapped memory identifiers. For example with respect to a memory identifier, false negative results would indicate that a subject memory identifier is not included in the set of remapped memory identifiers when indeed the subject memory identifier is included in the set of remapped memory identifiers. The operational result of such false negative indication by the mapping filter is that the memory location corresponding to the subject memory identifier would not be determined by the remapping mechanism. Instead, the memory location corresponding to the subject memory identifier would be determined by a previous, e.g., original, mapping mechanism. If the subject memory identifier was remapped due to failure of the memory location determined by the previous, e.g., original, mapping mechanism, the subject memory identifier would be mapped to the failed memory location and a data storage error possibly occurs.

False positive results from the mapping filter may be less problematic. A false positive indication of the mapping filter would indicate that the subject memory identifier is included in the set of remapped memory identifier (when indeed it was not previously remapped). As a result, determination of the memory location according to the remapping mechanism would be attempted, either by look-up, or deterministically, or by some other technique. The subject memory identifier may be remapped to a new memory location even though the previous memory location to which the subject memory identifier was mapped may not be failed, resulting in inefficient waste of available memory, e.g., non-failed memory location not being utilized. However, a data storage error should not occur as a direct result of the inefficiency.

According to some embodiments, since the subject memory identifier has not actually been remapped, determination of the memory location by the remapping mechanism might fail, e.g., fail to find reference to the subject memory identifier in a look-up table, so the mapping of the subject memory identifier may be configured to fail back to be determined by the previous, e.g., original, mapping mechanism. Again, no data storage error should occur since the memory location corresponding to the subject memory identifier (as determined by a previous, e.g., original, mapping mechanism) is not failed (and not actually remapped).

According to various embodiments of the present disclosure, the mapping filter is configured such that false negatives indications are not permitted. The mapping filter may, or may not, permit false positive indications according to various embodiments. One such filter that may provide no false negative indications is a Bloom filter. According to alternative embodiments, a mapping filter with a small quantity and/or probability of false negatives can be utilized, e.g., small relative to memory design error rate criteria.

A Bloom filter is a space-efficient probabilistic data structure that can be used to test whether an element is a member of a set. False positive matches are possible, but false negatives are not, i.e., a query returns either “possibly in set” or “definitely not in set.” Elements can be added to the set, but generally cannot be removed without introducing a possibility of false negative matches. The more elements that are added to the set, the larger the probability of false positives for a given bit array size.

An empty Bloom filter is an array of m bits, all set to a first data state, e.g., 0. A number, n, of different hash functions are defined, each of which hashes, e.g., maps, a subject element to one of the m bit array positions, preferably with a uniform random distribution. To add a subject element to the set of elements, the subject element is processed according to each of the n hash functions to determine n array positions, and the bits at these positions are set to a second data state, e.g., 1.

To subsequently query whether a subject element is included in the set of elements, the subject element is processed according to each of the n hash functions to determine the corresponding n array positions. If any of the bits at these array positions are set to the first data state, e.g., 0, the element is definitely not in the set. If the subject element were included in the set of elements, then the bits at all of the corresponding n array positions would have been set to the second data state, e.g., 1, when the subject element was inserted into the set of elements. If all of the bits at the corresponding n array positions are set to the second data state, e.g., 1, then the subject element may be in the set of elements. That is, either the element is in the set, or the bits have been set to the second data state during the insertion of other elements, resulting in a false positive for the subject element being tested. Although it may be possible to distinguish a positive from a false positive result in a simple Bloom filter, but more advanced techniques can be used to address this problem.

FIG. 2 shows mapping filter 208 having a number of hash functions, H₀ 210-0, H₁ 210-1, . . . , Hₙ 210-n. A set of included elements {x, y, z} 214 is shown being processed by the mapping filter to produce respective hash outputs. For example, element x as processed by hash function H₀ 210-0 is indicated as h₀(x) and corresponds to array bit 4 of array 212, which is shown being set to the second data state, e.g., 1, indicative of inclusion. Element x as processed by hash function H₁ 210-1 is indicated as h₁(x) and corresponds to array bit 12, which is shown being set to the second data state, e.g., 1, indicative of inclusion, and element x as processed by hash function Hₙ 210-n is indicated as hₙ(x) and corresponds to array bit 16, which is shown being set to the second data state, e.g., 1, indicative of inclusion. Bits of array 212 corresponding to array positions determined by the number of hash functions can be set as elements are added to the set. Where the elements are memory identifiers, for example, bits of array 212 can be set as each subject memory identifier is added to the set of remapped memory identifiers.

Element y as processed by hash function H₀ 210-0 is indicated as h₀(y) and corresponds to array bit 1, which is shown being set to the second data state, e.g., 1, indicative of inclusion. Element y as processed by hash function H₁ 210-1 is indicated as h₁(y) and corresponds to array bit 8, which is shown being set to the second data state, e.g., 1, indicative of inclusion, and element y as processed by hash function Hₙ 210-n is indicated as hₙ(y) and corresponds to array bit 13, which is shown being set to the second data state, e.g., 1, indicative of inclusion. Element z as processed by hash function H₀ 210-0 is indicated as h₀(z) and corresponds to array bit 8, which is shown being set to the second data state, e.g., 1, indicative of inclusion. Element z as processed by hash function H₁ 210-1 is indicated as h₁(z) and corresponds to array bit 12, which is shown being set to the second data state, e.g., 1, indicative of inclusion, and element z as processed by hash function Hₙ 210-n is indicated as hₙ(z) and corresponds to array bit 14, which is shown being set to the second data state, e.g., 1, indicative of inclusion. Array bits 8 and 12 are each set to the second data state by the hashing of multiple elements corresponding to the particular array bit.

In subsequently testing respective ones of the x, y, or z elements to see if they are included in the set of elements indicated by the Bloom filter 208, the respective elements are again processed by the hash functions of the Bloom filter to determined corresponding array 212 bit positions. Determination that all of the determined corresponding array 212 bit positions are set to the second data state, e.g., 1, indicates that the respective element is included in the set of elements indicated by the Bloom filter.

FIG. 2 also illustrates a mapping filter operation for an element not included in a set between a processor and a memory in accordance with a number of embodiments of the present disclosure. Element r is not included in the set of elements {x, y, z} 214 by which the corresponding bits of array 212 were set. To test element r with filter 208, element r can be processed by the hash functions of filter 208 to determine the corresponding bit positions of array 212.

Element r as processed by hash function H₀ 210-0 is indicated as h₀(r) and corresponds to array bit 3, element r as processed by hash function H₁ 210-1 is indicated as h₁(r) and corresponds to array bit 8, and element r as processed by hash function Hₙ 210-n is indicated as hₙ(r) corresponds to array bit 14. Although array bit 8 and 14 are set to the second data state, e.g., 1, indicative of inclusion, array bit 3 is set to the second data state (which it would have been had element r been included in the set of elements {x, y, z} 214 by which the corresponding bits of array 212 were set. As such, array 212 indicates that element r is not in the set of elements {x, y, z} 214 by which the corresponding bits of array 212 were set.

The Bloom filter can be appropriately sized, e.g., more bits in the array, and tuned to limit the occurrence of false positives within desired limits. The hash functions utilized by the Bloom filter can be different independent hash functions with a wide output and little, if any, correlation between different bit-fields of such a hash. Embodiments of the present disclosure can utilize Bloom filters of varying complexity.

Removing an element from a Bloom filter is generally not possible without introducing undesirable false negatives. An element maps to n array bits, and although setting any one of the corresponding n bits back to the first data state, e.g., 0, operates to remove the element, changing an array bit from a second data state back to the first data state can also result in removing any other elements that happen to map onto that array bit. Determining whether any other elements have been added that affect a particular array bit can be burdensome. One-time removal of an element from a Bloom filter can be simulated by having a second Bloom filter that contains items that have been removed. However, false positives in the second filter become false negatives in the composite filter, which may be undesirable. In this approach re-adding a previously removed item is not possible, as one would have to remove it from the “removed” filter.

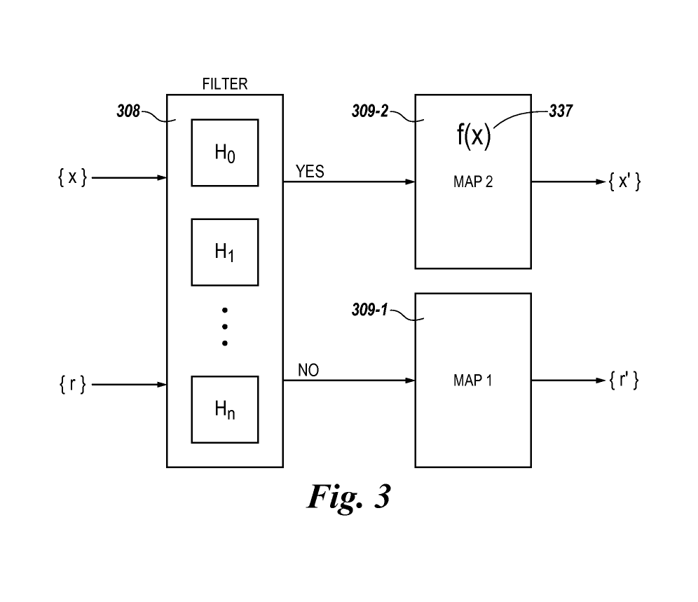

FIG. 3 illustrates mapping utilizing a filter and associative data structure in accordance with a number of embodiments of the present disclosure. According to various embodiments of the present disclosure, a two-part process can be used to determine memory mapping. A memory location corresponding to the memory identifier is determined responsive to the memory identifier being tested against an indication corresponding to a set of mapped memory identifiers. For example, a two-part process can be used. First, a filter, e.g., a Bloom filter, can be used to quickly determine if a memory location is mapped according to a first mapping or a second mapping. Second, the determined mapping is used to determine the corresponding memory location. For example, a filter can be used to quickly determine if a memory location is mapped according to a first, e.g., an original, mapping or according to a second, e.g., remapped, mapping. When used to determine whether a memory identifier has been remapped, for example, each memory identifier can be tested against the memory mapping filter to determine which mapping should be subsequently used to determine a memory location that corresponds to the memory identifier.

FIG. 3 shows a mapping filter 308, e.g., a Bloom filter, and a secondary mapping mechanism 309-2. Mapping filter 308 can be analogous to mapping filter 108 shown in FIG. 1 and mapping filter 208 shown in FIG. 2. Primary mapping mechanism 309-1 can be analogous to first mapping mechanism 109-1 shown in FIG. 1, and secondary mapping mechanism 309-2 can be analogous to second mapping mechanism 109-2 shown in FIG. 1. As shown in FIG. 3, when an element, e.g., x, is included in the set of elements, e.g., {x, y, z} 214 shown in FIG. 2, by which the filter is configured to indicate possible inclusion, the secondary mapping mechanism 309-2 can be selected. The element can be presented to selected secondary mapping mechanism 309-2 to determine a corresponding mapping, e.g., x′. For example, a memory identifier x, e.g., processor-side address, which is indicated by the filter as possibly being included in the set of remapped memory identifiers, causes mapping filter 308 to select the secondary mapping mechanism 309-2. That is, memory identifier x previously corresponded to a failed memory location, and memory identifier x has been remapped to a new memory location. As such, memory identifier x can be presented to the secondary mapping mechanism 309-2 for processing to determine a corresponding memory location, x′.

According to various embodiments, the secondary mapping mechanism 309-2 can be an associative data structure such as a look-up table, for example. According to some embodiments, the secondary mapping mechanism 309-2 can be a deterministic remapping mechanism, as shown in FIG. 3 by the secondary mapping mechanism 309-2 implementing function f(x) 337. A deterministic remapping mechanism can be implemented, for example, from bits of a memory identifier processed by function(s), e.g., hash functions, to determine, e.g., compute the corresponding remapped memory location. However, a deterministic remapping mechanism and/or an associative data structure that automatically remaps can have a disadvantage of some memory locations being wasted for false positives indicated by the mapping filter if no corrective action is taken to remove same. According to some embodiments, the mapping filter, e.g., Bloom filter, can be tuned to minimize false positives to a greater degree where a deterministic remapping mechanism is utilized, for instance.

When an element, e.g., r, is not included in the set of elements, e.g., {x, y, z} 214 shown in FIG. 2, for which the filter is configured to indicate possible inclusion, the primary mapping mechanism 309-1 can be selected. The element can be presented to primary mapping mechanism 309-1 to determine a corresponding mapping, e.g., r′. For example, a memory identifier r, e.g., a processor-side address r, which is not indicated by the filter as being included in the set of remapped memory identifiers, causes mapping filter 308 to select the primary mapping mechanism 309-1. That is, memory identifier r did not previously corresponded to a failed memory location, and memory identifier r has not been remapped to a new memory location. As such, memory identifier r can be presented to the primary mapping mechanism 309-1 for processing to determine a corresponding memory location, r′.

FIG. 4 is a block diagram of an apparatus in the form of a computing system 440 including a memory device 444 in accordance with a number of embodiments of the present disclosure. As used herein, a memory device 444, a memory array 446, and/or sensing circuitry 458 might also be separately considered an “apparatus.” According to various embodiments of the present disclosure, a memory mapping module, including filter(s) and plurality of mapping mechanisms, can be implemented in various manners between the host 442 and the memory array 446, such as at the host, in control circuitry 448, and/or address circuitry 450, among others.

System 440 includes a host 442 coupled to memory device 444, which includes a memory array 446. Host 442 can be a host system such as a personal laptop computer, a desktop computer, a digital camera, a mobile telephone, or a memory card reader, among various other types of hosts. Host 442 can include a system motherboard and/or backplane and can include a number of processing resources, e.g., one or more processors, microprocessors, or some other type of controlling circuitry. The system 440 can include separate integrated circuits or both the host 442 and the memory device 444 can be on the same integrated circuit. The system 440 can be, for instance, a server system and/or a high performance computing (HPC) system and/or a portion thereof. Although the example shown in FIG. 4 illustrates a system having a Von Neumann architecture, embodiments of the present disclosure can be implemented in non-Von Neumann architectures, e.g., a Turing machine, which may not include one or more components, e.g., CPU, ALU, etc., often associated with a Von Neumann architecture.

For clarity, the system 440 has been simplified to focus on features with particular relevance to the present disclosure. The memory array 446 can be a DRAM array, SRAM array, STT RAM array, PCRAM array, TRAM array, RRAM array, NAND flash array, and/or NOR flash array, for instance. The array 446 can comprise memory cells arranged in rows coupled by access lines (which may be referred to herein as word lines or select lines) and columns coupled by sense lines (which may be referred to herein as digit lines or data lines). Although a single array 446 is shown in FIG. 4, embodiments are not so limited. For instance, memory device 444 may include a number of arrays 446, e.g., a number of banks of DRAM cells.

The memory device 444 includes address circuitry 450 to latch address signals provided over an I/O bus 464, e.g., a data bus, through I/O circuitry 452. Address signals are received and decoded by a row decoder 454 and a column decoder 460 to access the memory array 446. Data can be read from memory array 446 by sensing voltage and/or current changes on the sense lines using sensing circuitry 458. The sensing circuitry 458 can read and latch a page, e.g., row, of data from the memory array 446. The I/O circuitry 452 can be used for bi-directional data communication with host 442 over the I/O bus 464. The write circuitry 456 is used to write data to the memory array 446.

Control circuitry 448 decodes signals provided by control bus 462 from the host 442. These signals can include chip enable signals, write enable signals, and address latch signals that are used to control operations performed on the memory array 446, including data read, data write, and data erase operations. In various embodiments, the control circuitry 448 is responsible for executing instructions from the host 442. The control circuitry 448 can be a state machine, a sequencer, or some other type of controller.

In a number of embodiments, the sensing circuitry 458 can comprise a number of sense amplifiers and a number of compute components, which may comprise an accumulator and can be used to perform logical operations, e.g., on data associated with complementary sense lines. In a number of embodiments, the sensing circuitry, e.g., 458, can be used to perform logical operations using data stored in array 446 as inputs and store the results of the logical operations back to the array 446 without transferring via a sense line address access, e.g., without firing a column decode signal. As such, various compute functions can be performed within/using sensing circuitry 458 rather than being performed by processing resources external to the sensing circuitry, e.g., by a processor associated with host 442 and/or other processing circuitry, such as ALU circuitry, located on device 444 such as on control circuitry 448 or elsewhere. In various previous approaches, data associated with an operand, for instance, would be read from memory via sensing circuitry and provided to external ALU circuitry via local I/O lines. The external ALU circuitry would perform compute functions using the operands and the result would be transferred back to the array via the local I/O lines. In contrast, in a number of embodiments of the present disclosure, sensing circuitry, e.g., 458, is configured to perform logical operations on data stored in memory, e.g., array 446, and store the result to the memory without enabling a local I/O line coupled to the sensing circuitry.

As such, in a number of embodiments, circuitry external to array 446 and sensing circuitry 458 is not needed to perform compute functions as the sensing circuitry 458 can perform the appropriate logical operations to perform such compute functions without the use of an external processing resource. Therefore, the sensing circuitry 458 may be used compliment and/or to replace, at least to some extent, such an external processing resource (or at least the bandwidth of such an external processing resource). However, in a number of embodiments, the sensing circuitry 458 may be used to perform logical operations, e.g., to execute instructions, in addition to logical operations performed by an external processing resource, e.g., host 442. For instance, host 442 and/or sensing circuitry 458 may be limited to performing only certain logical operations and/or a certain number of logical operations.

FIG. 5 illustrates a block diagram of an apparatus in the form of a computing device 570 including a memory device 574 and a number of requesting devices 572, 576, 580 in accordance with a number of embodiments of the present disclosure. Examples of requesting devices can include a processor 572, a DMA device 576, and/or a memory unit 580, among others. The processor(s) 572 can be analogous to the processors 102-1, . . . , 102-P illustrated in FIG. 1. The memory unit 580 can be analogous to the memory 104 illustrated in FIG. 1 and/or to another memory unit other than memory 104. The computing device 570 can be analogous to the computing device 100 illustrated in FIG. 1. In FIG. 5, more detail is shown regarding a specific example of a memory 574 that is a hybrid memory cube (HMC). The memory HMC 574 illustrated in FIG. 5 can be analogous to the memory devices 104-1, . . . , 104-M illustrated in FIG. 1.

According to various embodiments of the present disclosure, a memory mapping module, including filter(s) and plurality of mapping mechanisms, can be implemented in various manners between the processor(s) 572 and the memory HMC 574, such as in control circuitry described below.

An HMC 574 can be a single package including multiple memory devices 578-1, 578-2, 578-3, . . . , 578-B, e.g., DRAM dies, and hardware logic device 582, e.g., a logic die, application-specific integrated circuit (ASIC), corresponding logic in another device, etc., stacked together using through silicon vias (TSV), although other embodiments may differ, e.g., the hardware logic device 582 may not necessarily be stacked with the memory devices 578. The memory within the HMC 574 can be organized into subsets, e.g., vaults, 584, where each vault 584 is functionally and operationally independent of other vaults 584. Each vault 584 can include a partition of memory from each of the memory devices 578. Each vault 584 can include a hardware logic unit 588, e.g., vault controller, in the logic device 582 that functions analogously to a memory controller for the vault 584. Each vault controller 584 can be coupled to a respective subset of the plurality of memory devices 578. For example, the vault controller 588 can manage memory operations for the vault 584 including determining its own timing requirements, e.g., instead of being managed by a requesting device such as a processor. The vault controller 588 can include a number of buffers for requests and responses with a processor 572 and can utilize the number of buffers to send responses to the processor 572 out of order with respect to an order in which the requests were received from the processor 572. Thus, the processor 572 can be configured to send a request via an interface to the HMC 574 without being aware of a read time associated with the request.

FIG. 5 includes an illustration of a more detailed view of a logic device 582 coupled between the memory devices 578 and the requesting devices 572, 576, 580. The logic base 582 can include memory control logic 588 for each vault, e.g., vault control. The vault controller 588 can be coupled to a shared memory control logic 590 for the HMC 574 that can consolidate functions of the vaults 584. However, the shared memory control logic 590 does not necessarily comprise a central memory controller in the traditional sense because each of the vaults 584 can be directly controlled, e.g., controlled timing, access, etc., independently of each other and because the shared memory control logic 590 does not necessarily interface, e.g., directly interface, with the requesting devices 572, 576, 580. Thus, in some embodiments, the computing device 570 and/or the memory 574 does not include a central memory controller. The memory control logic 590 can be coupled to a switch 592, e.g., a crossbar switch. The switch 592 can provide availability of the collective internal bandwidth from the vaults 584 to the input/output (I/O) links 596. The switch 592 can be coupled to link interface controllers 594, which control I/O links 596 to a requesting device 572, 576, 580. For example, the I/O links 596 can be serial fully duplexed input/output links. The logic device 582 can provide a logical/physical interface for the memory 574.

The memory 574 can receive requests from requesting devices such as a processor 572, a DMA device 576, and/or a memory unit 580, among others. As described herein, in some embodiments, the memory 574 can be configured to provide an indication that locations in the memory 574, from which data is gathered, are unavailable until the gathered data is released by the requesting device 572, 576, 580. Such embodiments can provide a synchronization mechanism, e.g., so that stale data is not delivered in response to a request from the DMA device 576 while the data is being operated on by the processor 572.

The present disclosure includes apparatuses, electronic device (e.g., computing device) readable media, and methods for memory controlled data movement and timing. A number of electronic device readable media store instructions executable by an electronic device to provide programmable control of data movement operations within a memory (e.g., a memory). The memory can provide timing control, independent of any associated processor, for interaction between the memory and the associated processor. As used herein, “memory” does not necessarily have to be volatile memory, and can in some embodiments be non-volatile memory.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and methods are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method for memory mapping, comprising:
testing a memory identifier against an indication corresponding to a set of mapped memory identifiers to determine to which memory mapping the memory identifier is presently subject; and
determining a memory location corresponding to the memory identifier responsive to testing.

2. The method of claim 1, wherein testing the memory identifier against the indication corresponding to the set of mapped memory identifiers to determine to which memory mapping the memory identifier is presently subject comprises testing to determine if the memory identifier may have been remapped from another memory mapping.

3. The method of claim 1, wherein testing the memory identifier against the indication corresponding to the set of mapped memory identifiers to determine to which memory mapping the memory identifier is presently subject comprises testing to determine whether the memory identifier may be subject to an alternative memory mapping.

4. The method of claim 3, wherein determining the memory location corresponding to the memory identifier responsive to testing comprises determining the memory location corresponding to the memory identifier using another memory mapping responsive to determining that the memory identifier is not subject to the alternative mapping.

5. The method of claim 3, wherein determining the memory location corresponding to the memory identifier responsive to testing comprises determining the memory location corresponding to the memory identifier responsive to testing using the alternative mapping responsive to determining that the memory identifier is subject to the alternative mapping.

6. The method of claim 1, wherein testing a memory identifier against an indication corresponding to a set of mapped memory identifiers to determine to which memory mapping the memory identifier is presently subject comprises testing the memory identifier to dynamically select between memory mappings.

7. The method of claim 1, wherein the memory identifier is subject to a first memory mapping under a first condition and is subject to a second memory mapping under a second condition.

8. The method of claim 1, wherein determining the memory location includes:
determining the memory location corresponding to the memory identifier according to a first mapping responsive to the testing indicating that the memory identifier is not included in the set of mapped memory identifiers; and
determining the memory location corresponding to the memory identifier according to a second mapping responsive to the testing indicating that the memory identifier is included in the set of mapped memory identifiers.

9. The method of claim 8, wherein determining the memory location corresponding to the memory identifier according to the second mapping includes looking-up a memory location corresponding to the memory identifier in an associative data structure.

10. The method of claim 9, wherein the associative data structure is a data table indexed by the memory identifier.

11. The method of claim 8, wherein determining the memory location corresponding to the memory identifier according to the second mapping includes deterministically mapping the memory identifier to a physical memory location.

12. The method of claim 1, wherein testing the memory identifier against the indication corresponding to the set of mapped memory identifiers includes testing the memory identifier using a memory identifier filter.

13. The method of claim 12, wherein the memory identifier filter is configured to provide the indication such that false negatives are not permitted, a false negative being an indication of the memory identifier not being included in the set of mapped memory identifiers when it actually is in the set of mapped memory identifiers.

14. The method of claim 12, wherein the memory identifier filter is configured to utilize a number of different hash functions that hashes a member of the set of mapped memory identifiers to a respective filter array position.

15. The method of claim 14, wherein testing the memory identifier using a memory identifier filter includes testing the memory identifier using a Bloom filter.

16. The method of claim 14, wherein testing the memory identifier using a memory identifier filter includes testing the memory identifier using a skip list.

17. A method for memory mapping, comprising:
determining with a filter whether a memory identifier may be mapped according to an alternative memory mapping; and
determining a memory location corresponding to the memory identifier according to another memory mapping responsive to determining the memory identifier is not mapped according to the alternative memory mapping.

18. The method of claim 17, wherein determining with the filter comprises determining with a Bloom filter.

19. The method of claim 17, wherein determining with a filter comprises determining with a skip list.

20. The method of claim 17, further comprising:
determining with the filter whether another second memory identifier may be mapped according to the alternative memory mapping; and
determining another memory location corresponding to the other memory identifier according to the alternative memory mapping responsive to determining the other memory identifier may be mapped according to the alternative memory mapping.

21. The method of claim 17, further comprising:
determining with the filter whether another memory identifier may be mapped according to the alternative memory mapping; and
determining another memory location corresponding to the other memory identifier according to the other memory mapping responsive to determining the other memory identifier is not mapped according to the alternative memory mapping.

22. The method of claim 17, further comprising:
determining with the filter whether another memory identifier may be mapped according to the alternative memory mapping;
determining another memory location corresponding to the other memory identifier according to the other memory mapping responsive to determining the other memory identifier is not mapped according to the alternative memory mapping;
remapping the other memory identifier according to the alternative memory mapping responsive to determining the other memory location is failed; and
re-tuning the filter to indicate that the other memory identifier is mapped according to the alternative memory mapping.

23. The method of claim 17, further comprising:
determining with the filter whether another memory identifier may be mapped according to the alternative memory mapping;
determining whether the other memory identifier is mapped according to the alternative memory mapping responsive to determining that the other memory identifier may be mapped according to the alternative memory mapping; and
determining another memory location corresponding to the other memory identifier according to the other memory mapping responsive to determining the other memory identifier is not mapped according to the alternative memory mapping.

24. The method of claim 17, wherein the other memory mapping comprises a previous memory mapping and the alternative memory mapping comprises a subsequent memory mapping.

25. The method of claim 17, wherein the other memory mapping comprises a default memory mapping.

26. The method of claim 17, wherein the other memory mapping comprises a primary memory mapping and the alternative memory mapping comprises a secondary memory mapping.

27. A method for memory mapping, comprising:
testing a memory identifier for exclusion from a group of memory identifiers; and
selecting a memory mapping from among a plurality of memory mappings responsive to testing the memory identifier for exclusion from the group of memory identifiers.

28. The method of claim 27, wherein selecting the memory mapping includes selecting a first memory mapping when the memory identifier tests as excluded from the group of memory identifiers and selecting a second memory mapping when the memory identifier tests as not excluded from the group of memory identifiers.

29. The method of claim 27, wherein selecting the memory mapping includes selecting an associative data structure memory mapping mechanism when the memory identifier tests as excluded from the group of memory identifiers and selecting a deterministic memory mapping mechanism when the memory identifier tests as not excluded from the group of memory identifiers.

30. The method of claim 27, wherein selecting the deterministic memory mapping mechanism includes computing a memory location based on data comprising the memory identifier.

31. The method of claim 27, wherein selecting the memory mapping includes selecting a first associative data structure memory mapping mechanism when the memory identifier tests as excluded from the group of memory identifiers and selecting a second associative data structure memory mapping mechanism when the memory identifier tests as not excluded from the group of memory identifiers.

32. The method of claim 27, further comprising testing each memory identifier for exclusion from the group of memory identifiers.

33. The method of claim 27, further comprising determining a memory location corresponding to the memory identifier according to the selected memory mapping.

34. The method of claim 27, wherein:
testing the memory identifier for exclusion from the group of memory identifiers comprises testing the memory identifier for exclusion from a plurality of groups of memory identifiers,
wherein selecting the memory mapping comprises selecting the memory mapping from among the plurality of memory mappings responsive to testing the memory identifier for exclusion from the plurality of groups of memory identifiers, and
wherein testing utilizes a plurality of filters.

35. An apparatus, comprising:
memory; and
a memory mapping module configured to:
test a memory identifier for exclusion from a group of mapped memory identifiers; and
determine a memory location corresponding to the memory identifier responsive to the test of the memory identifier.

36. The apparatus of claim 35, further comprising a processing resource and an interface between the memory and the processing resource, wherein the memory mapping module is included in the interface.

37. The apparatus of claim 35, wherein the memory comprises a memory device wherein the memory mapping module is associated with the memory device.

38. The apparatus of claim 35, further comprising a host, and wherein the memory comprises a memory array and the memory mapping module is between the host and the memory array.

39. The apparatus of claim 38, wherein the memory mapping module is at the host.

40. The apparatus of claim 38, wherein the memory mapping module is in control circuitry configured to control operations performed on the memory array.

41. The apparatus of claim 38, wherein the memory mapping module is in address circuitry coupled to the memory array.

42. The apparatus of claim 35, wherein the memory mapping module includes a filter configured to select a memory mapping from among a plurality of memory mappings, the selected memory mapping being configured to determine the memory location corresponding to the memory identifier.

43. The apparatus of claim 35, wherein the filter is configured to provide no false negative results with respect to inclusion of the memory identifier in the group of mapped memory identifiers.

44. The apparatus of claim 35, wherein the filter is a Bloom filter.

45. The apparatus of claim 35, wherein the filter is a skip list.

46. The apparatus of claim 35, wherein the group of mapped memory identifiers is a group of remapped memory identifiers, and the memory mapping module is configured to determine the memory location from an associative data structure where the memory identifier is excluded from the group of remapped memory identifiers and further configured to determine the memory location from a different associative data structure where the memory identifier is not excluded from the group of remapped memory identifiers.

47. The apparatus of claim 35, wherein the group of mapped memory identifiers is a group of remapped memory identifiers, and the memory mapping module is configured to determine the memory location from an associative data structure where the memory identifier is excluded from the group of remapped memory identifiers and further configured to compute the memory location from the memory identifier where the memory identifier is not excluded from the group of remapped memory identifiers.

48. The apparatus of claim 35, wherein the apparatus comprises a hybrid memory cube (HMC).

49. A non-transitory electronic device readable medium storing a set of instructions executable by an electronic device to:
test a memory identifier for exclusion from a group of memory identifiers; and
select a memory mapping from among a plurality of memory mappings responsive to testing the memory identifier.

50. The medium of claim 49, wherein the set of instructions is executable by an electronic device to:
test the memory identifier for exclusion from a group of mapped memory identifiers; and
select an alternate memory mapping responsive to the memory identifier not being excluded from the group of mapped memory identifiers.
